(19) United States
(12) Patent Application Publication
(10) Pub. No.: US 2002/0084502 A1
(43) Pub. Date: Jul. 4, 2002

(54) Carbon nanotip and fabricating method thereof

(76) Inventors: Jin Jang, Seoul (KR); Sung-Hoon Lim, Seoul (KR); Hong-Sik Kim, Seoul (KR)

Correspondence Address: BIRCH STEWART KOLASCH & BIRCH, PO BOX 747, FALLS CHURCH, VA, 22040-0747, US

(21) Appl. No.: 10/028,302

(22) Filed: Dec. 28, 2001

(30) Foreign Application Priority Data
Dec. 29, 2000 (KR) 2000-0084943
May 10, 2001 (KR) 2000-0025503
May 16, 2001 (KR) 2001-0026717

(51) Int. Cl. H01L 31/0232

(52) U.S. Cl. 257/432; 257/144; 257/192

(57) ABSTRACT

A carbon nanotip and method of fabrication, wherein a carbon nanotip includes a silicon-metal alloy (MeₓSi₁₋ₓ) on a silicon substrate, a carbon graphite phase on the silicon-metal alloy and a nanotip.

### BACKGROUND OF THE INVENTION

1. Field of the Invention

The present invention relates to a carbon nanotip and to a fabricating method thereof, and more particularly, to a uniform high-density nanotip and fabricating method thereof using plasma chemical vapor deposition.

2. Background of the Related Art

Currently, many efforts have been made to develop nano-sized materials using carbon, such as for example, carbon nanotube, fulleren, and the like. Specifically, carbon nanotubes attract attention as a field emission device for a field emission display (FED) of a next generation flat panel display (FPD) to which many studies have been made [S. Uemura, T. Nagasako, J. Yotani, T. Shimojo, and Y. Saito, SID'98 Digest, 1052 (1988)].

In a FED based on electron emission in a vacuum, a micro-sized tip (previously, single crystalline Si, MO, W) emits electrons by a strong electric field to cause a fluorescent material to emit light, thereby providing excellent brightness and resolution as well as a small size and light-weight. Carbon nanotube for a field emission device have a diameter of a nanometer, thereby providing a high degree of strength. Particularly, carbon nanotubes have a low electron emission field (below about 1 V/μm) and a large emission current. Yet, carbon nanotube should be mixed with an epoxy, or the like, thereby experiencing difficulty in being used for a field emission device [W. B. Choi, D. S. Chung, S. H. Park, and J. M. Kim, SID'99 Digest, 1135 (1999)].

Recently, Professor Ren of New York University succeeded in fabricating a carbon nanotube arranged on a glass substrate using ‘Plasma-high temperature filament CVD’ [Z. F. Ren et al., Science 283, 512 (1999)]. Professor Fan of Stanford University has succeeded in depositing a carbon nanotube selectively on an iron metal of a patterned substrate using CVD [Shoushan Fan et al., Science 283, 512 (1999)] to be directly used for the field emission device of a carbon nanotube. However, the carbon nanotubes fabricated by such methods fail to show effective adhesiveness to a substrate and further contain the disadvantages or problems in realizing a FED of high resolution due to the difficulty in patterning. Moreover, the carbon nanotube failed to provide excellent uniformity and stability in electron emission.

However, compared to a thermal electron emission display device, the carbon nanotube has a high and uniform electron emission, sufficient brightness, and long durability. Therefore, the carbon nanotube is being studied for its application to CRT (cathode ray tubes), and VFD (vacuum fluorescence display) [Y. Saito, S. Uemura Carbon 38, 169 (2000)].

### SUMMARY OF THE INVENTION

A carbon nanotip according to the present invention provides excellent adhesiveness to a substrate, an electron emission turn-on field (<0.2 V/μm) lower than that of the carbon nanotube, excellent uniformity and stability of electron emission, and application to a high definition electron emission display, thanks to the feasibleness for patterning a catalyst metal.

Moreover, the carbon nanotip according to the present invention having an electron emission field is applicable widely to various electronic devices with ease, using electron emission, which is a new carbon nanomaterial having never been reported.

Accordingly, the present invention is directed to a carbon nanotip and fabricating method thereof that substantially obviates one or more of the problems, limitations and disadvantages of the related art.

Accordingly, an object of the present invention is to provide a carbon nanotip and fabricating method which provides a high substrate generating density and a uniformity of the nanotip using chemical vapor deposition (hereinafter abbreviated CVD).

Another object of the present invention is to provide a method of fabricating a nanotip having a high uniformity and generation density using CVD.

A further object of the present invention is to use the carbon nanotip of the present invention as an electron emission device for an electron emission display and the like.

Another further object of the present invention is to fabricate a 3-electrode tube using the carbon nanotip according to the present invention.

Additional advantages, objects, and features of the invention will be set forth in part in the description which follows and in part will become apparent to those having ordinary skill in the art upon examination of the following or may be learned from the practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, a method of fabricating a carbon nanotip according to the present invention includes the steps of depositing a catalyst metal on a silicon wafer, forming a silicide by heating the metal, and forming naturally a tip by exposing the surface of the silicide to a carbon plasma including carbon atoms.

In another aspect of the present invention, a carbon nanotip includes a silicon-metal alloy (MeₓSi₁₋ₓ) on a silicon substrate, a carbon graphite phase on the silicon-metal alloy and a nanotip.

In a further aspect of the present invention, a light emitting apparatus includes a body to which a power is applied, a cathode formed of a carbon nanotip at an inner bottom of the body, a gate formed of a metal net over the cathode, and an anode formed of a fluorescent material at the top of the body.

It is to be understood that both the foregoing general description and the following detailed description of the present invention are exemplary and explanatory and are intended to provide further explanation of the present invention.

### BRIEF DESCRIPTION OF THE DRAWINGS

The accompanying drawings, which are included to provide a further understanding of the present invention and are incorporated in and constitute a part of this application, illustrate embodiment(s) of the invention and together with the description serve to explain the principle of the invention.

FIG. 1 illustrates schematic cross-sectional views of a method for fabricating a carbon nanotip according to the present invention;

FIG. 2 illustrates a plane SEM (scanning electron microscope) picture of carbon nanotips according to the present invention;

FIG. 3 illustrates a cross-sectional SEM picture of carbon nanotips according to the present invention;

FIG. 4 illustrate a cross-sectional dark sight image TEM (transmission electron microscope) picture and its magnification of a carbon nanotip, according to the present invention;

FIG. 5A illustrates a magnified high resolution cross-sectional bright sight image TEM (transmission electron microscope) picture of carbon nanotips (A in FIG. 4) according to the present invention;

FIG. 5B illustrates a magnified high resolution cross-sectional bright sight image TEM (transmission electron microscope) picture of carbon nanotips (A) in FIG. 4) according to the present invention;

FIG. 5C illustrates a magnified high resolution cross-sectional bright sight image TEM (transmission electron microscope) picture of carbon nanotips (b) in FIG. 4) according to the present invention;

FIG. 6A illustrates a TEM picture of an electron diffraction pattern for the carbon part of the nanotips according to the present invention;

FIG. 6B illustrates a TEM picture of an electron diffraction pattern for the silicide part of the nanotips according to the present invention;

FIG. 7 illustrates a graph of an AES (Auger electron spectroscopy) analysis of carbon nanotips according to the present invention;

FIG. 8 illustrates a graph of the electron emission characteristics of carbon nanotips according to the present invention;

FIG. 9 illustrates a light-emitting apparatus according to the present invention;

FIG. 10 illustrates an example for a graph of electron emission characteristics of carbon nanotips according to the present invention; and

FIG. 11A and FIG. 11B illustrate pictures of luminesceit characteristics of a carbon nanotip lamp according to the present invention.

### DETAILED DESCRIPTION OF THE INVENTION

Reference will now be made in detail to the preferred embodiments of the present invention, examples of which are illustrated in the accompanying drawings.

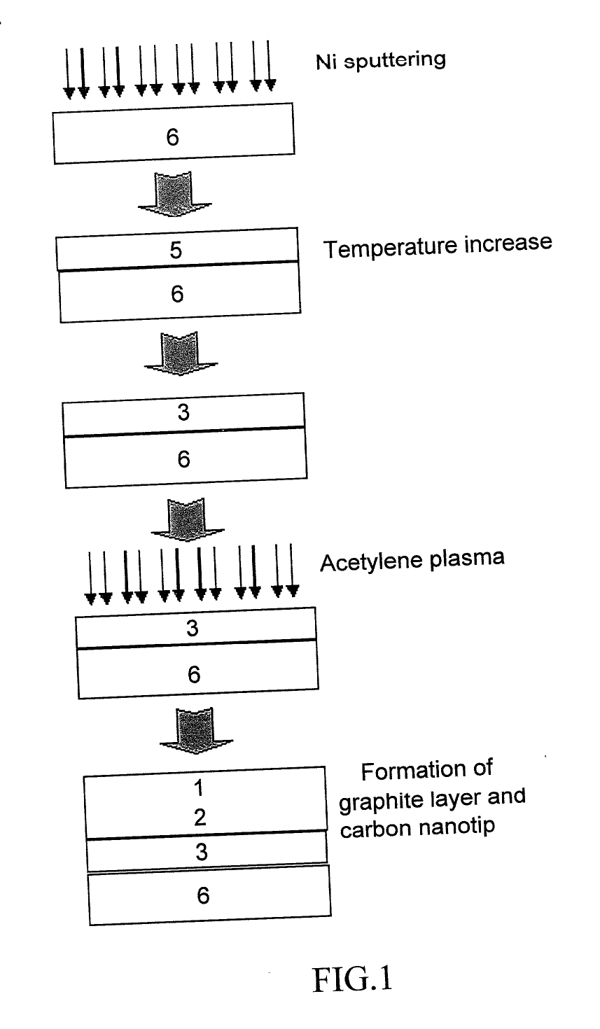

FIG. 1 illustrates schematic cross-sectional views of the method for fabricating a carbon nanotip according to the present invention.

Referring to FIG. 1, the method of fabricating a carbon nanotip according to the present invention includes the steps of depositing a metal on a silicon wafer, forming a silicide by heating the metal, and forming naturally a tip by exposing a surface of the silicide to a plasma including carbon atoms.

The metal used in the step of depositing the metal is a generation catalyst of a carbon nanotip such as a transition metal. This embodiment according to the present invention uses Ni as the metal. Alternatively, a metal which facilitates the formation a silicide, such as Co or the like is also applicable as the generation catalyst. In this case, the transition metal is deposited about 5 to 200 nm thick onto a quartz substrate or a crystalline silicon substrate by sputtering.

After the deposition of the metal on the substrate, in order to increase the characteristics and generation density of a nanotip, NH₃ plasma treatment is carried out on the surface of the metal for several tens of seconds to several minutes. The exposure time is preferably set less than 30 minutes.

Carbon plasma is used for the step of forming the nanotip. In this case, acetylen (C₂H₂) or methane (CH₄) or a mixture thereof is used as the carbon source of the carbon gas. The carbon gas is decomposed by an RF (radio frequency) power of 13.56 MHz so as to generate the carbon nanotip. In this case, a flow of the carbon gas is 25 sccm, the RF power is preferably fixed to 1 KW for the deposition, the substrate temperature is 500 to 900° C., and an internal pressure is preferably lower than 1 Torr. The plasma used in the step of forming the nanotip is inductively-coupled plasma of which density is preferably maintained over 10¹¹ cm⁻³.

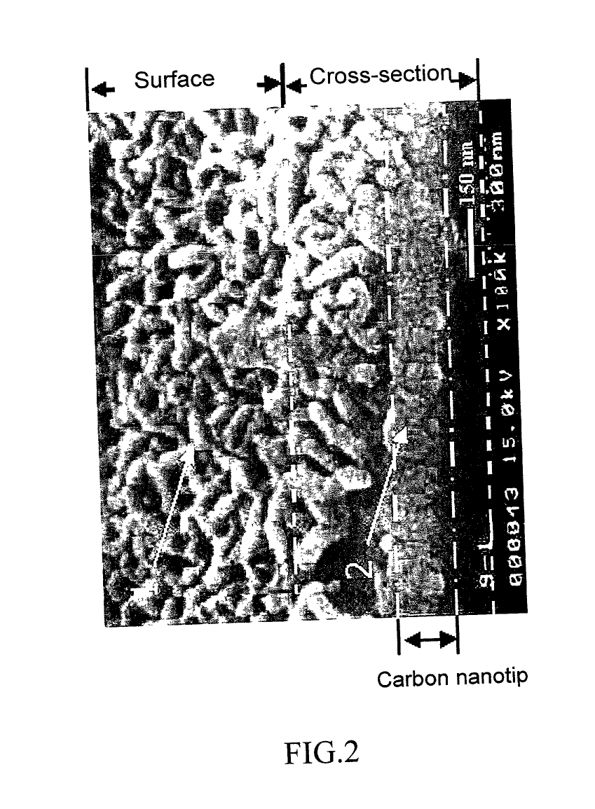

FIG. 2 illustrates a plane SEM (scanning electron microscope) picture of carbon nanotips according to the present invention.

Referring to FIG. 2, a plurality of nanotips are grown uniformly on a surface of a substrate where a catalyst metal is deposited. A growing direction of the carbon nanotip is irregular. Yet, it can be seen that a large number of tips have grown in a direction vertical to the substrate. The carbon nanotip grows only from a spot or location where the catalyst metal exists, and fails to grow on a silicon or quartz substrate free from the catalyst metal.

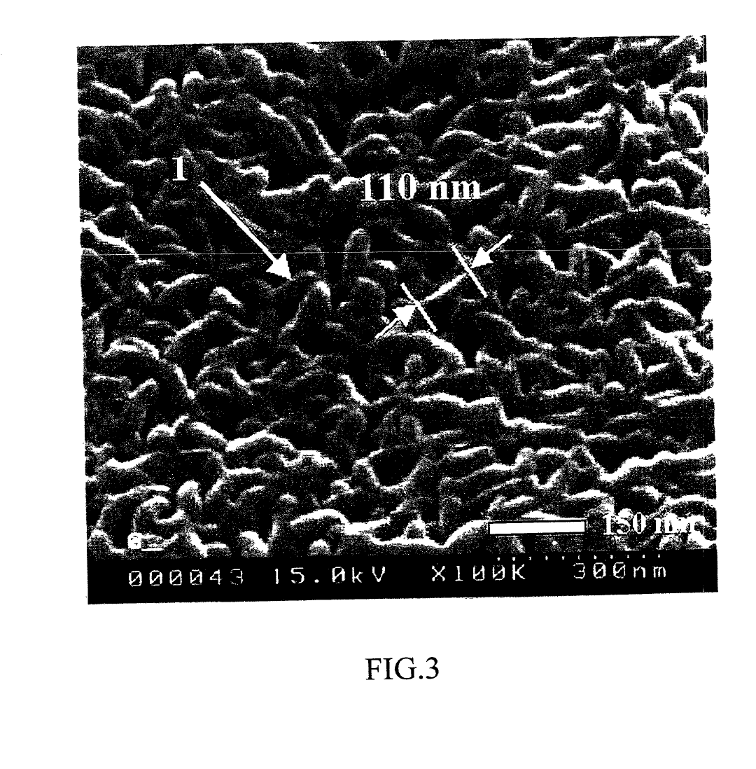

FIG. 3 illustrates a cross-sectional SEM picture of carbon nanotips according to the present invention.

Referring to FIG. 3, a graphite layer is formed of several to tens of nm on a substrate where a catalyst metal is deposited. Carbon nanotips are formed on the graphite layer. The carbon nanotips are formed on the basis of the graphite layer having a crystalline structure.

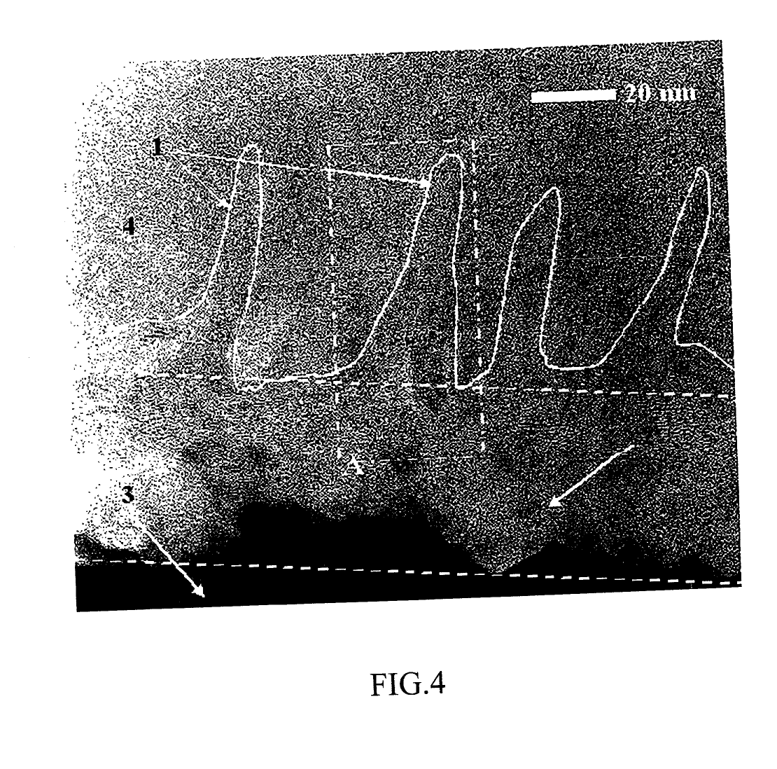

FIG. 4 illustrate a cross-sectional dark sight image TEM (transmission electron microscope) picture and one of its magnified carbon nanotips according to the present invention.

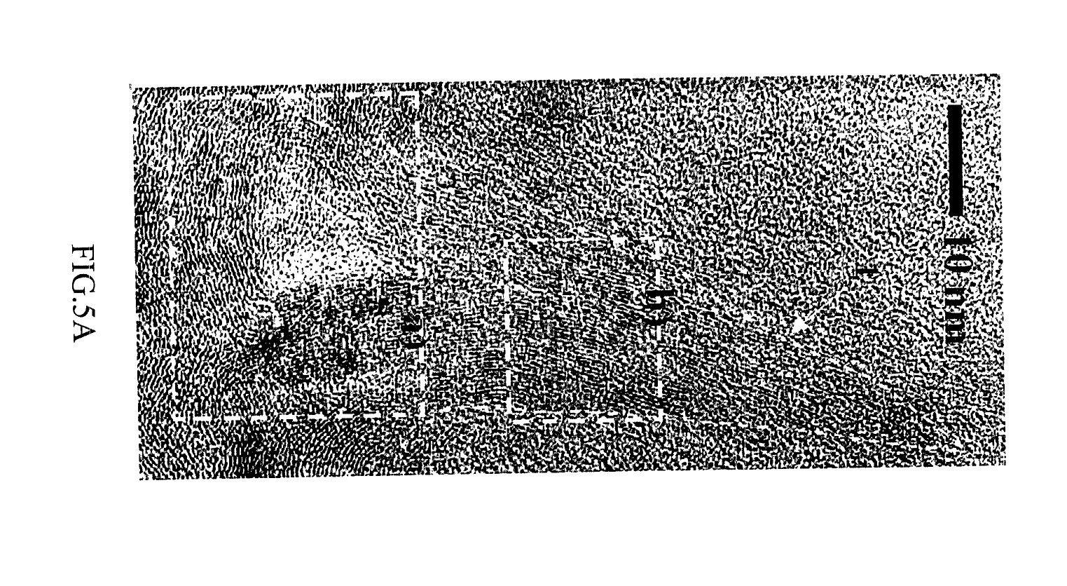

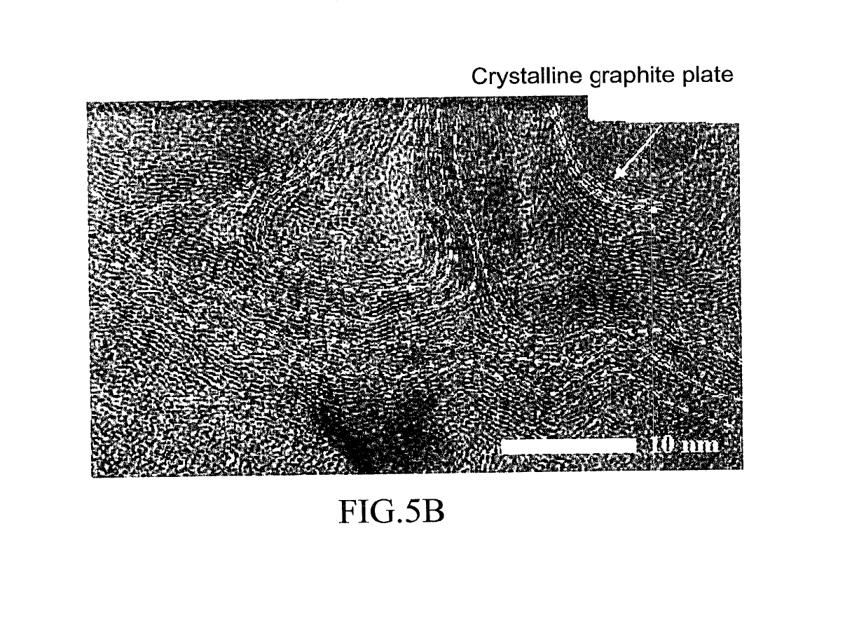

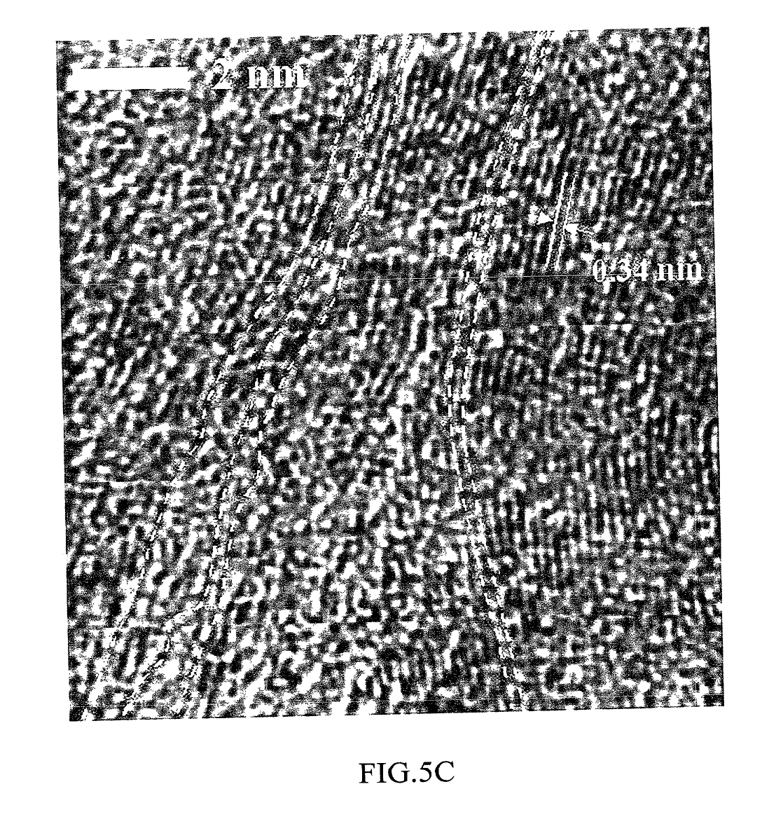

Referring to FIG. 4, carbon nanotips are in epoxy used for preparing a TEM sample. It is seen that the carbon nanotips are arranged in a vertical direction to a plane. In the drawings, a silicon layer constructing a substrate, a silicide layer, a graphite layer, and nanotips are stacked in order. The epoxy is used for fixing the sample prepared for taking a cross-sectional TEM picture. The graphite layer is formed about 35 nm thick below the carbon nanotips. The thickness of the graphite layer may vary from 10 to 100 nm in accordance with the deposition time and temperature of the nanotips. A crystalline structure of nanotips is confined in the epoxy. The dark portion in FIG. 4 is the silicide 3 comprising silicon and nickel. A crystalline graphite phase 2 is grown on the silicide 3. The carbon nanotips 1 are grown on the crystalline graphite phase 2. A portion designated by a closed line A indicates one of the carbon nanotips, of which a magnified picture is shown in FIG. 5A.

FIG. 5A illustrates a magnified high resolution cross-sectional bright sight image TEM (transmission electron microscope) picture of the carbon nanotips (A in FIG. 4) according to the present invention.

Referring to FIG. 5A, a crystalline structure of carbon nanotips is well shown. The carbon nanotips 1 are grown on a crystalline graphite phase 2. And, most of the carbon nanotips 1 grow in a direction substantially vertical to a substrate.

FIG. 5B illustrates a magnified high resolution cross-sectional bright sight image TEM (transmission electron microscope) picture of carbon nanotips (A) in FIG. 4 according to the present invention.

Referring to FIG. 5B, carbon nanotips 1 are grown from a graphite phase 2 forming a crystalline structure.

FIG. 5C illustrates a magnified high resolution cross-sectional bright sight image TEM (transmission electron microscope) picture of carbon nanotips (b) in FIG. 5A according to the present invention.

Referring to FIG. 5C, a body of a carbon nanotip is shown to present a crystalline structure of graphite. Each interval between layers of the crystalline structure is 0.34 nm, which corresponds to an interlayer distance of crystalline graphite.

In a structure of the carbon nanotips according to the present invention, as shown in FIG. 5A to FIG. 5C, stacked in order are a silicon-metal alloy MeₓSi₁₋ₓ, where x is between 0.3 and 0.7, disposed on a substrate, a carbon graphite phase, and carbon nanotips. The metal silicide is formed to be about 5 to 200 nm thick. The carbon graphite phase is formed to be about 10 to 100 nm thick. The carbon material becomes irregular by irradiation of the plasma.

Each of the carbon nanotips has a crystalline graphite structure in which the distance between carbon layers is 0.34 nm. The carbon nanotips are only formed on the catalyst metal at a thickness of 50 to 300 nm and in irregular shapes.

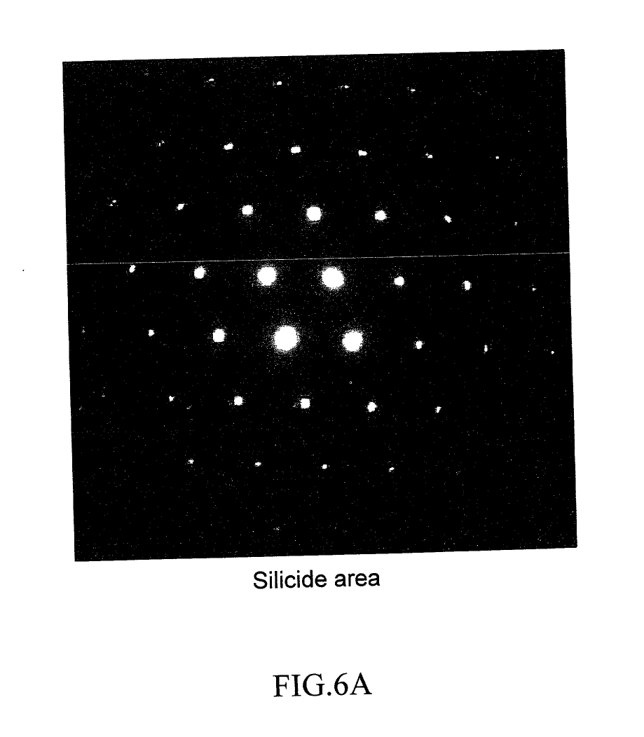

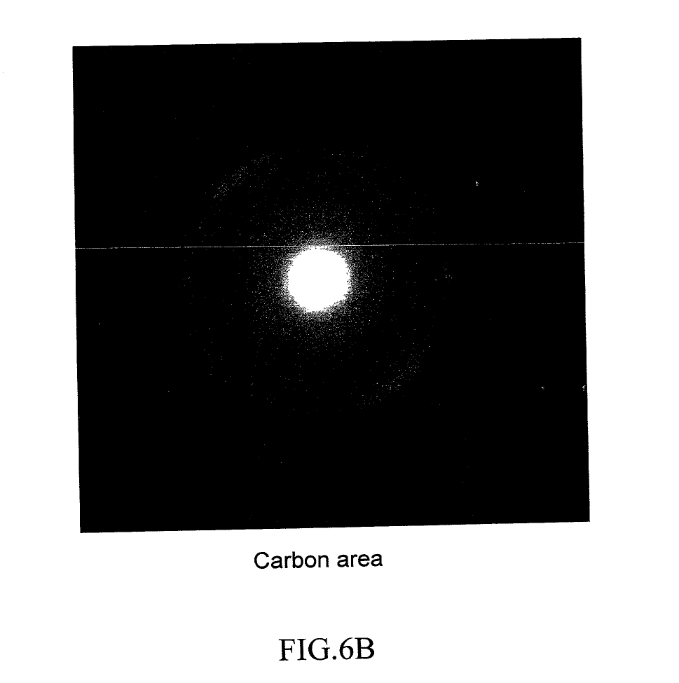

FIG. 6A illustrates a TEM picture of an electron diffraction pattern for a carbon portion of the nanotips according to the present invention.

Referring to FIG. 6A, the diffraction pattern indicates that the carbon portion is constructed with carbon atoms, and the ring pattern shows that the crystalline directions of the nanotips are not uniform but variable, which is caused by the crystalline graphite layer disposed below the nanotips.

FIG. 6B illustrates a TEM picture of an electron diffraction pattern for a silicide portion of the nanotips according to the present invention.

Referring to FIG. 6B, it is indicated that the direction of a diffraction pattern of NiSi₂ silicide coincides with that of silicon. Namely, it is seen that Ni used as a catalyst metal is changed into NiSi₂ silicide during the growth of carbon nanotips. It is presumed that the formation of the silicide is one of the major factors for carbon nanotip growth.

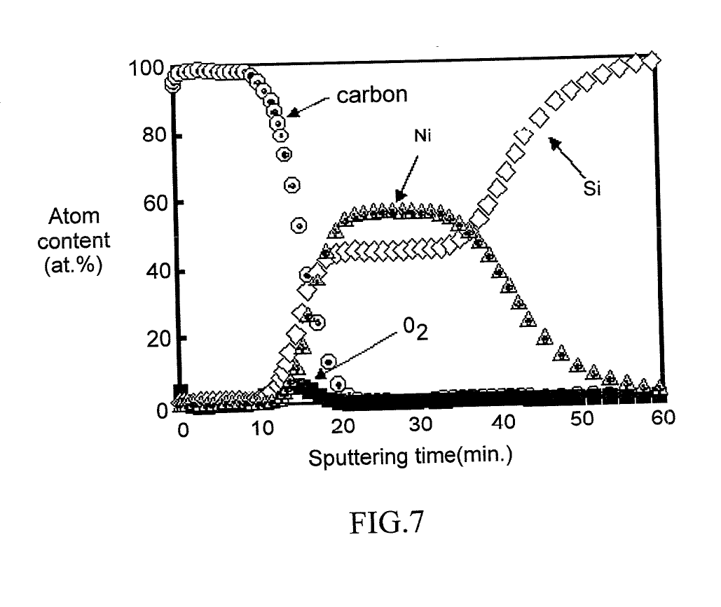

FIG. 7 illustrates a graph of AES (Auger electron spectroscopy) analysis of carbon nanotips according to the present invention.

Referring to FIG. 7, a carbon peak shows up only at the surface of the sample. As sputtering time increases, silicon and nickel peaks show up together. Thus, it is presumed that nickel deposited on silicon diffuses inside silicon so as to form the silicide. Namely, silicon-nickel alloy, carbon graphite phase, and carbon nanotips are stacked on a silicon substrate in that order.

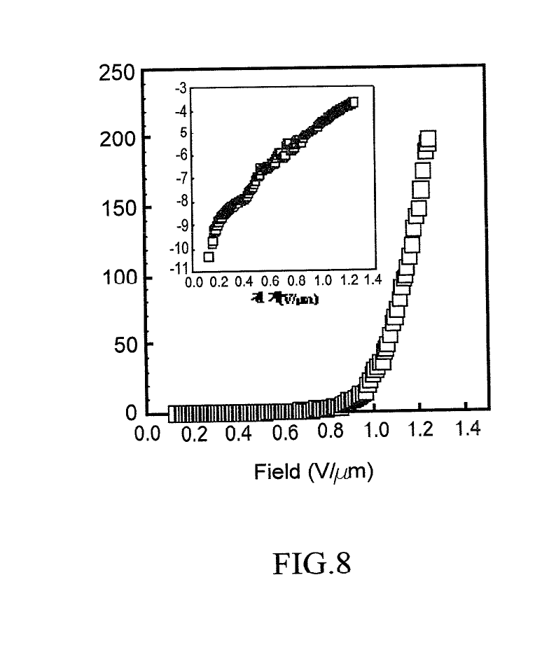

FIG. 8 illustrates a graph of electron emission characteristics of carbon nanotips according to the present invention.

Referring to FIG. 8, a characteristic graph for field emission of nanotips has a turn-on field of 0.1 V/μm, and shows an excellent field electron emission characteristic having a current density of 98 μA/cm² at a field of 1.25 V/μm. The turn-on field of 0.1 V/μm is about ten times less than that of 1 V/μm of generally-reported carbon nanotubes, thereby exhibiting a low turn-on field.

Such nanotips as an electron emission device according to the present invention are applicable to lamps.

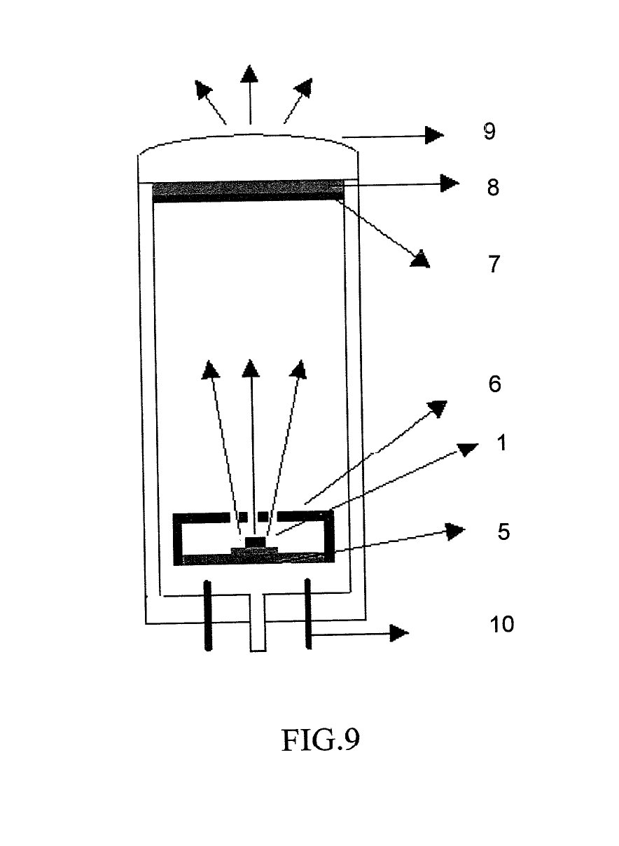

FIG. 9 illustrates a light-emitting apparatus according to the present invention.

Referring to FIG. 9, a lamp 10 includes a carbon nanotip of the present invention as a cathode 1, a metal net as a gate 6, and a fluorescent material as an anode 8, thereby constituting a 3-electrode light-emitting apparatus according to the present invention.

The shell of the lamp 10 is a glass tube, and the degree of vacuum inside the lamp 10 is 10⁻⁶ Torr.

The cathode 1 for measuring the luminescent characteristic is formed on a ceramic substrate 5, and the carbon nanotip as the cathode 1 is preferably formed to cover an area of 1 to 100 mm². The metal net 6 is formed to cover an area of 1 to 10 mm², and the distance between the cathode 1 and gate 6 is preferably maintained to about 0.1 to 10 mm.

The cathode 1 uses the carbon nanotip according to the present invention and, as mentioned in the above description, has a stacked structure of carbon nanotip/graphite layer/metal silicide/silicon. The graphite layer is formed 0 to 100 nm thick, with a radius of the carbon nanotip of about 1 to 1000 nm, and a height of the carbon nanotip of preferably about 10 to 1000 nm.

The anode 8, formed on the aluminum layer 7, is made of a fluorescent material which substantially emits light. The anode 8 is coated with a phosphor covering an area having a diameter of about 5 to 24 mm. The distance between the anode 8 and gate 6 is preferably maintained at about 0.2 to 100 mm. A glass lens 9 is installed at an outer surface of the anode 8 so as to concentrate the light-emitting source.

The diameter and length of the lamp 10 are preferably 10˜29 mm and 10˜120 mm, respectively. A vacuum exhaust of 10⁻⁷ Torr is maintained inside the lamp 10, and a voltage of 100˜1,400 V is applied between the cathode 1 and gate 6. A voltage of 1˜35 KV is applied to the anode 8.

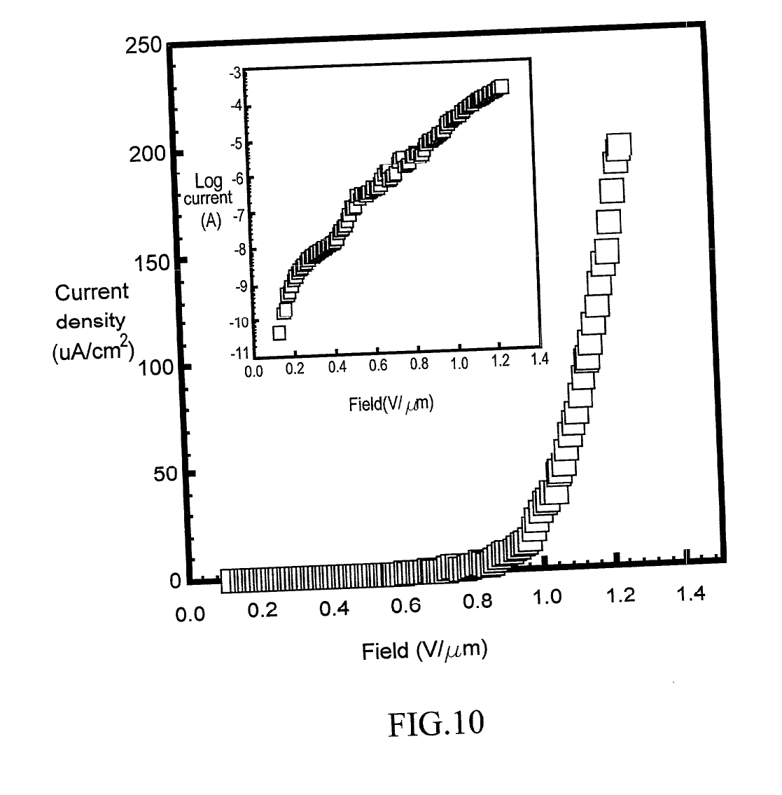

FIG. 10 illustrates a graph showing the electron emission characteristics of the carbon nanotips according to the present invention.

Referring to FIG. 10, a characteristic graph for field emission of nanotips has a turn-on field of 0.1 V/μm, and shows an excellent field electron emission characteristic having a current density of 98 μA/cm² at a field of 1.25 V/μm. The turn-on field of 0.1 V/μm is about ten times less than that of 1 V/μm of generally-reported carbon nanotubes, thereby showing a very low turn-on field.

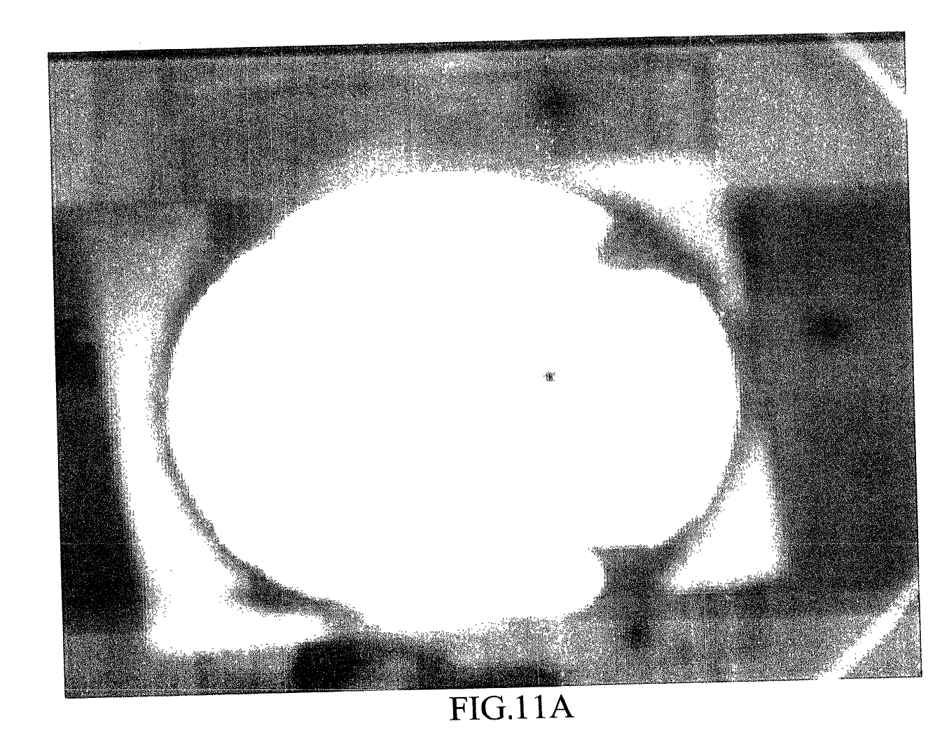

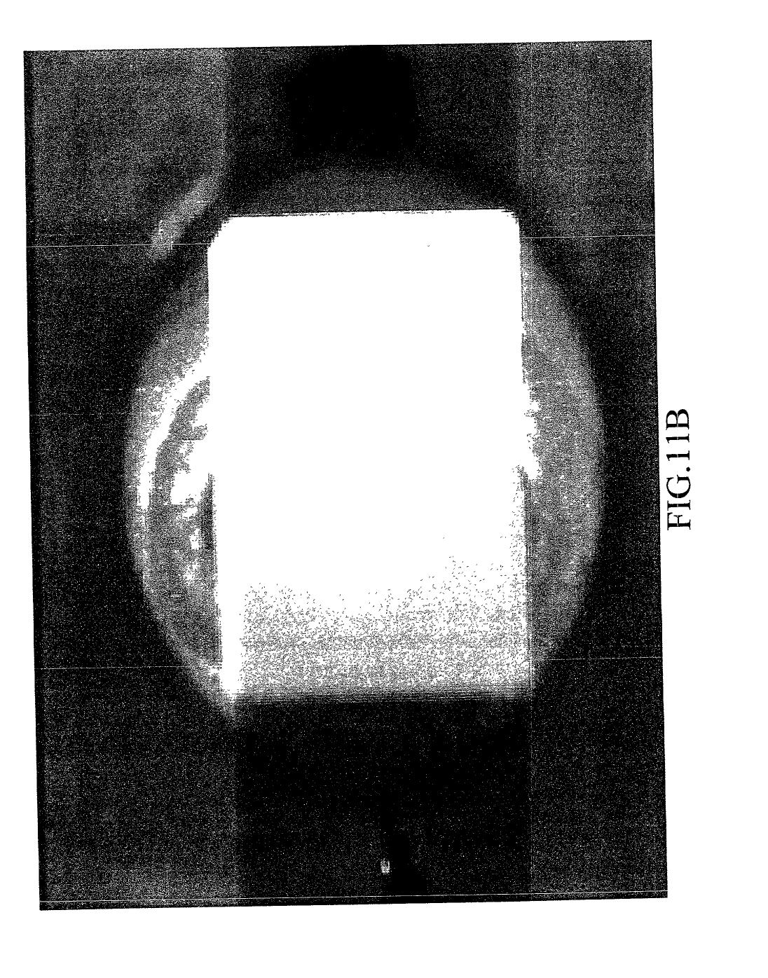

FIG. 11A and FIG. 11B illustrate pictures of luminescent characteristics of a carbon nanotip lamp according to the present invention.

Referring to FIG. 11A and FIG. 11B, it is seen that uniform and strong light is emitted from the whole surface of a lamp anode.

In this case, the area of the carbon nanotips as a cathode is prepared to be 1.0 mm². The diameter of the anode is 20 mm. A metal net as a gate covers an area of 3 mm². The distance between the cathode and the gate is maintained at 0.7 mm, and the distance between the gate and anode is 60 mm. The diameter of the glass tube of the lamp is 29 mm, and the length of the glass tube is 80 mm. A voltage of 1,400 V is applied between the cathode and gate, and a voltage of 10 KV is applied to the anode. An emitting color in FIG. 11A is red, while that in FIG. 11B is green.

The present invention brings about the following effects or advantages. The carbon nanotip according to the present invention has excellent adhesiveness to a substrate, an electron emission turn-on field lower than that of carbon nanotubes, and an emission current larger than that of nanotubes, thereby making them applicable to an electron emission source for all kinds of electronic equipments using electron emission such as SEM, TEM, and the like.

The carbon nanotip light-emitting apparatus according to the present invention has uniform and strong light-emitting characteristics, thereby rendering it applicable to backlights of a TFT-LCD and a LCD-projector, an outdoor display module, special lighting displays, thanks to the beautiful colors, and the like.

Moreover, the present invention has electron emission characteristics more excellent than that of other electron emission devices of related art. Therefore, the present invention provides a technology for producing a cold cathode lamp, thereby facilitating the development of the lamp industry and display industry.

Furthermore, the present invention provides a new concept for a high brightness light source, thereby being applicable to all kinds of electronic devices.

The forgoing embodiments are merely exemplary and are not to be construed as limiting the present invention. The present teachings can be readily applied to other types of devices. The description of the present invention is intended to be illustrative, and not to limit the scope of the present invention. Thus, many alternatives, modifications, and variations will be apparent to those skilled in the art.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A method of fabricating a carbon nanotip, comprising the steps of:
depositing a metal catalyst on a silicon wafer;
forming a silicide by heating the metal; and
forming naturally a tip by exposing a surface of the silicide to carbon plasma including carbon atoms.

2. A method of fabricating a carbon nanotip, comprising the steps of:
depositing silicon on an insulating substrate;
depositing a metal catalyst on the silicon;
forming a silicide by heating the metal; and
forming naturally a tip by exposing a surface of the silicide to carbon plasma including carbon atoms.

3. The method of claim 1, wherein the metal catalyst is nickel.

4. The method of claim 1, wherein the metal catalyst is 5 to 200 mm thick.

5. The method of claim 1, wherein the metal catalyst is exposed to NH₃ plasma.

6. The method of claim 5, wherein the metal catalyst is exposed to the NH₃ plasma for a time of less than 30 minutes.

7. The method of claim 1, wherein the carbon plasma is generated from a gas mixture of C₂H₂ or CH₄ with NH₃ or H₂.

8. The method of claim 1, wherein the carbon plasma uses inductively-coupled plasma.

9. The method of claim 8, wherein the a density of the plasma is over 10¹¹ cm⁻³.

10. A carbon nanotip comprising:
a silicon-metal alloy (MeₓSi₁₋ₓ) disposed on a silicon substrate;
a carbon graphite phase disposed on the silicon-metal alloy; and
a nanotip formed on the carbon graphite phase.

11. The carbon nanotip of claim 10, wherein x in the MeₓSi₁₋ₓ is between 0.3 and 0.7.

12. The carbon nanotip of claim 10, wherein the metal of the silicon-metal alloy is nickel.

13. The carbon nanotip of claim 10, wherein the carbon material is irregularly formed by plasma irradiation.

14. The carbon nanotip of claim 10, wherein the carbon graphite has a thickness of about 10 to 100 nm.

15. The carbon nanotip of claim 10, wherein the distance between the nanotip and the carbon layer is 0.34 nm.

16. The carbon nanotip of claim 10, wherein the nanotip has a thickness of about 50 to 300 nm.

17. The carbon nanotip of claim 10, wherein the silicon-metal alloy has a thickness of about 5 to 200 nm.

18. The carbon nanotip of claim 10, wherein the nanotip is only formed on the metal catalyst.

19. The carbon nanotip of claim 10, wherein the nanotip is irregularly formed.

20. A light emitting apparatus comprising:
a body to which power is applied;
a cathode formed of a carbon nanotip and provided at an inner bottom of the body;
a gate formed of a metal net and provided over the cathode; and
an anode formed of a fluorescent material and provided at the top of the body.

21. The light emitting apparatus of claim 20, wherein a distance between the cathode and gate is between about 0.1 and 10 mm.

22. The light emitting apparatus of claim 20, wherein an area of the carbon nanotip is between about 1 and 100 mm².

23. The light emitting apparatus of claim 20, wherein a distance between the gate and anode is between about 0.2 and 10 cm.

24. The light emitting apparatus of claim 20, wherein an area of the metal net is between about 0.1 and 1.0 cm².

25. The light emitting apparatus of claim 20, wherein the carbon nanotip is structural in a nanotip/graphite, layer/metal, and silicide/silicon configuration.

26. The light emitting apparatus of claim 25, wherein the metal silicon is nickel silicide.

27. The light emitting apparatus of claim 20, wherein the graphite layer is about 0 to 100 nm thick.

28. The light emitting apparatus of claim 20, wherein the carbon nanotip has an irregular configuration.

29. The light emitting apparatus of claim 18, wherein a radius of the carbon nanotip is between about 1 and 1000 nm and has a height of between about 10 and 1000 nm.

30. A cathode formed with the carbon nanotip of claim 10.
